(19) United States
(12) Patent Application Publication
(10) Pub. No.: US 2021/0051825 A1
(43) Pub. Date: Feb. 18, 2021

(54) CIRCUIT BOARD ASSEMBLIES

(71) Applicant: Hewlett-Packard Development Company, L.P., Spring, TX (US)

(72) Inventors: Xavier Gomez Travesset, Sant Cugat del Valles (ES); Marc Clotet Marti, Sant Cugat del Valles (ES); Cesar Luis Coelho Morais De Serpa Rosa, Sant Cugat del Valles (ES)

(21) Appl. No.: 17/049,736

(22) PCT Filed: Jun. 15, 2018
(86) PCT No.: PCT/US2018/037847

§ 371 Date: Oct. 22, 2020

(51) Int. Cl. H05K 9/00; H05K 1/02; H05K 3/34

(52) U.S. Cl. CPC H05K 9/0028; H05K 3/3452; H05K 3/341; H05K 1/023

(57) ABSTRACT

In an example there is provided a method for electro-magnetically shielding a circuit board assembly. The method comprises depositing a solder material at multiple locations on a substrate, heating the solder material according to a predetermined thermal profile and coupling an enclosure to the substrate at the locations to provide an electromagnetic shielding for components attached to the substrate. The locations are arranged on the substrate such that a size of a largest aperture of the circuit board assembly is below a pre-determined threshold size value.

### BACKGROUND

Circuit boards may comprise large numbers of integrated electronic circuit components, Electronic circuits are vulnerable to harmful effects of electromagnetic radiation. Electromagnetic radiation from other components or background radiation can cause circuit errors or, in the worst case, failure of components. Equally electronic circuits produce electromagnetic radiation which can be harmful to components located near the circuit, Providing shielding around electronic components may help to reduce the harmful effects of electromagnetic radiation. However, electronic circuits rarely operate in isolation. Consequently, it is not possible to completely isolate a circuit from the surrounding environment. Shielding enclosure need to provide access holes to connect the circuit to further external circuits or power supplies. This may mean some electromagnetic radiation passes through the enclosure,

### BRIEF DESCRIPTION OF THE DRAWINGS

Various features of certain examples will be apparent from the detailed description which follows, taken in conjunction with the accompanying drawings, which together illustrate, by way of example, a number of features, wherein:

FIG. 1A is a block diagram of a circuit board assembly, according to an example,

FIG. 1B is a block diagram of a circuit board assembly, according to an example.

FIG. 2A is a block diagram of section of a circuit board assembly, according to an example.

FIG. 2B is a block diagram of section of a circuit board assembly, according to an example,

FIG. 2C is a block diagram of section of a circuit board assembly, according to an example.

FIG. 2D is a block diagram of section of a circuit board assembly, according to an example.

FIG. 3 is a block diagram of section of a circuit board assembly, according to an example.

FIG. 4 is a diagram showing a flow chart showing a method for electromagnetically shielding a circuit board assembly, according to an example.

FIG. 5 shows a processor associated with a memory and comprising instructions for providing a management system with a trustable management state according to an example.

### DETAILED DESCRIPTION

In the following description, for purposes of explanation, numerous specific details of certain examples are set forth. Reference in the specification to “an example” or similar language means that a particular feature, structure, or characteristic described in connection with the example is included in at least that one example, but not necessarily in other examples.

When an electronic device is exposed to electromagnetic radiation it may become subject to electromagnetic interface. Electromagnetic interference is a disturbance generated by an external source such as an electric field from another device or background radiation. Electromagnetic interference may affect the components of circuits in the electronic device by electromagnetic induction, electrostatic coupling, or conduction. Equally electronic circuits produce electromagnetic radiation which can be harmful to components located near the circuit, This disturbance can degrade performance of the circuit and other components near the circuit or even stop them from functioning altogether.

One way of protecting a device, if the device is likely to be exposed to a significant level of electromagnetic radiation is to provide appropriate shielding.

In some cases, it is of equal importance that the circuitry in the device is shielded to prevent the device itself producing electromagnetic radiation. For example, shielding may be used where a device or subcomponent of a device is within close proximity to another device to protect the components of the device(s) from one another.

A Faraday cage may be used to shield the components of an electronic device. A Faraday cage is an enclosure made from conductive material that is used to block electromagnetic radiation. An enclosure surrounding a circuit assembly will act as a Faraday cage to prevent electromagnetic radiation from entering or escaping if the conductive material it is made of is of a sufficient thickness and any apertures in the enclosure are significantly smaller than the wavelength of radiation that is being blocked.

Components of electronic devices are typically mounted on printed circuit boards (PCB) resulting in a printed circuit assembly (PCA). A PCA supports and electrically connects electronic components using conductive paths, pads and other features that are etched from layers of conductive material laminated onto or between sheet layers of a non-conductive substrate. Components may be soldered onto the PCB to both electrically connect and mechanically fasten them to it.

Various methods exist for mounting electronic components on to a PCB. One such method referred to as “through-hole technology” involves the use of leads or legs on the components which are inserted through holes that are drilled into the PCB. The additional process of drilling holes in the PCB prior to mounting the components means through-hole technology is more expensive and laborious when contrasted with other circuit construction methods.

Another method which has become ubiquitous is referred to as “surface mount technology” (SMT). In surface mounted devices i.e. those manufactured using SMT, electrical components are mounted and soldered directly on the surface of the PCB. In commercially produced electronic devices, SMT has largely replaced through-hole technology due to the lower manufacturing cost. In comparison to through-hole mounting, SMT allows smaller components to be mounted on to the PCB. This allows a higher density of components to be placed on a single PCB which further reduces manufacturing costs.

The methods and apparatus described herein relate to electromagnetically shielding a circuit board assembly. In particular, the methods and apparatus described herein may be used to enclose electronic components placed on a substrate of a circuit board assembly such that the largest aperture of the circuit board assembly including the enclosure surrounding the substrate is below a pre-determined threshold size value. By appropriately choosing a size value, the enclosure acts as a Faraday cage for the circuit board assembly. This ensures that no electromagnetic radiation escapes nor enters the assembly from outside of the enclosure. For this to be possible the largest aperture is smaller than the smallest wavelength of electromagnetic radiation which the circuit board assembly is being shielded against.

Herein “apertures” may refer to any holes in the circuit board assembly. This includes holes that are deliberately manufactured into the enclosure such that the circuit board assembly may be connected to, for example, other circuits or power supplies.

Apertures may also form where the enclosure contacts the substrate. In an scenario, the contact between the enclosure and the substrate is perfect, and no apertures form between the points of contact. However, in practice, due to deformations, bowing effects and non-linearity, the contact between the enclosure and the substrate is imperfect. Consequently, apertures form around the points of contact. To ensure that the resulting circuit board assembly forms a Faraday cage, the enclosure is fastened to the substrate at pre-determined locations. Fastening the enclosure ensures that the maximum aperture size is below a pre-determined threshold size. The largest aperture size is determined by selecting positions on the substrate to fasten the enclosure to the substrate.

There are a number of ways of fastening an enclosure to the substrate. For example, one possible method is to screw the enclosure to the substrate. An alternative option is to provide a mechanical element on the substrate to attach the enclosure to. Unfortunately, both these methods have the disadvantage that they use an additional manufacturing stage to fasten the enclosure to the substrate when used in conjunction with a SMT process. For example, in the case of screws, the electronic components are initially soldered on to the surface of the substrate, then the enclosure is subsequently screwed on. Holes are provided in the substrate in which to place the screws. Similarly to through-hole technology this use a further manufacturing step where the holes are drilled into the substrate.

The methods and apparatus described herein can be used in conjunction with surface mount technology. In the method described herein, the shielding enclosure is soldered on to the surface of the substrate. The locations at which solder material is placed to attach the enclosure are pre-determined. The solder material may be placed on the substrate as part of the SMT soldering process, i.e., while the solder material is placed on the substrate to secure the electrical components.

The methods described herein are compatible with existing SMT processes. The locations are pre-determined such that the largest aperture of the circuit assembly is sufficiently small that the surrounding enclosure acts as a Faraday cage. In particular, in contrast to other methods, the methods and apparatus described herein provide a more efficient and cheaper manufacturing method for an electromagnetically shielded circuit board assembly.

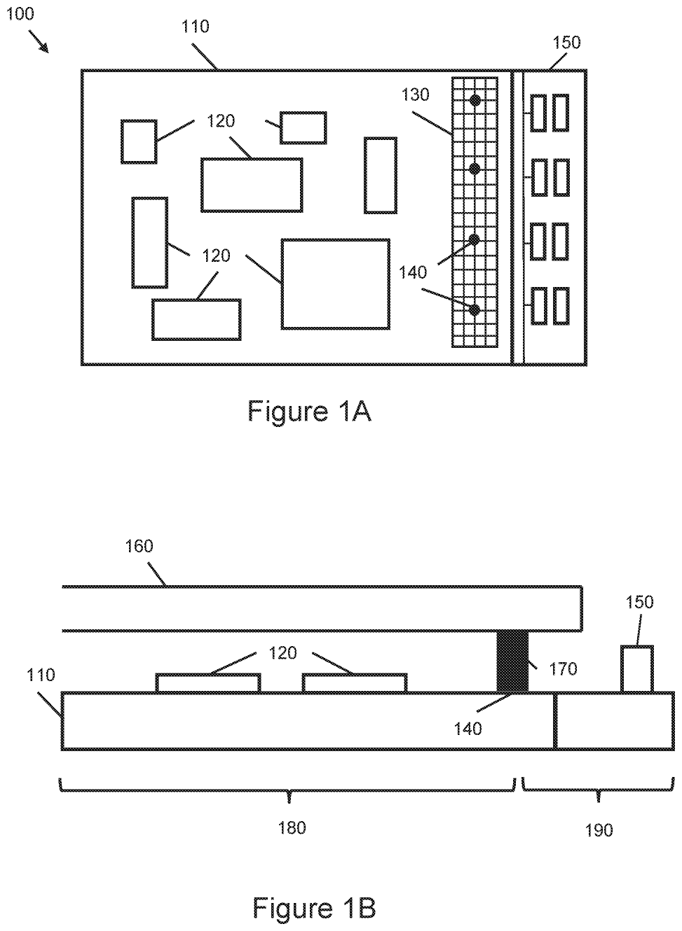

FIG. 1A is a simplified schematic diagram showing a circuit board 100, according to an example. The circuit board assembly shown in FIG. 1A comprises a substrate 110. The substrate 110 is, in certain examples, a PCB. The circuit board 100 further comprises a number of electrical components 120.

The electrical components 120 may be soldered on to the substrate 110. According to an example, the electrical components 120 are soldered on to the surface of the substrate 110 using a SMT process. In an SMT process the electrical components are placed on to the surface of the substrate 110. Solder material is placed around the components 120 to fix them in the desired locations on the substrate.

In FIG. 1A, the circuit board 100 further comprises a region 130. The region 130 is a region of the substrate 110 on to which solder material is placed to interconnect the substrate 110 to an enclosure. In FIG. 1A solder material is deposited on the region 130 at locations 140. An enclosure (not shown in FIG. 1A) is fitted to the substrate 110 at the locations 140 where solder material is deposited. FIG. 1A further shows a region 150 which contains one or more connecting elements that allow the circuit board to be connected to other components external to the circuit board 100. For example, in the case that the circuit board is a component in a larger machine, the connecting elements 150, which are external to any shielding allow the circuit board 100 to be connected to the machine. The connecting element(s) 150 are outside of the shielding otherwise the circuit board 100 would not be properly shielded.

FIG. 1B is a simplified schematic diagram showing a side view of the circuit board 100 shown in FIG. 1A, FIG. 1B further shows an enclosure 160 that at least partially surrounds the substrate 110. The enclosure 160 encloses at least some of the electrical components 120. In FIG. 1B, there is shown a protrusion 170 of solder material. The protrusion 170 may be located at one of the locations 140 shown in FIG. 1A. According to an example, the protrusion 170 may be a conductive metal such as tin. The protrusion 170 may be formed on the substrate 110 at the same time the solder material is deposited to fix the electrical components 120 to the substrate 110, e.g., by SMT soldering. According to an example, soldering material that forms the protrusion 170, such soldering material is heated in a manufacturing process according to a thermal profile. The thermal profile may specify a time period and temperature at which the solder material is to be heated to cause it to reflow.

According to examples herein, the locations 140 are pre-determined such that the size of the largest aperture that forms between the substrate and the enclosure is below a pre-determined threshold size. In particular, the locations 140 may be chosen such that the size of the largest aperture of the full circuit board assembly comprising the substrate, circuitry and enclosure, is sufficiently small that the enclosure forms a Faraday cage around the circuit board assembly, thus ensuring that no electromagnetic radiation can leak in or out of the assembly. In FIG. 1B the region 180 comprises the electromagnetically shielded region and the region 190 comprises the non-shielded region.

In order to ensure that an electrical component does not radiate electromagnetic radiation or receive electromagnetic radiation from outside of the assembly, the apertures in the Faraday cage is proportional to a wavelength determined from the frequency of the electrical signal associated to the component.

According to the theory of electromagnetism the Faraday cage will not permit electromagnetic radiation to be emitted or collected from outside the cage, when the maximum aperture in it has a maximum length of λ/4, were λ is the wavelength of the signal in the system having maximum frequency.

Consider a circuit comprising three electrical components that are connected to a substrate, where the components have frequencies of 200 MHZ, 333 MHz and 1 GHZ respectively.

The wavelength λ may be determined from the following formula:

$$λ = \frac{c}{F \cdot \sqrt{{c}_{reff}}} \qquad ( 1 )$$

In the formula (1) above, the quantity c corresponds to the velocity of light, F is the frequency of the signal measure in hertz and the quantity [symbol] is the (effective) Dielectric constant of the media where the signal is moving. In examples described herein the Dialectic constant has a value of approximately 3.

The λ value is determined for each of the components as follows:
200 MHz: λ=0,87 m
333 MHz: λ=0,52 m
1 GHz: λ=0,17 m

In the example above, since the maximum frequency F within the Faraday cage is 1 GHz, the maximum theoretical aperture size that the Faraday cage can have in order shield the components from electromagnetic radiation is 0.17/4 m=4.25 cm. However, according to empirical test results, having apertures of less than λ/4 does not guarantee that the Faraday cage will protect from all electromagnetic radiation. In practice, a maximum size of λ/20 will eliminate risks and unwanted circuit behaviour.

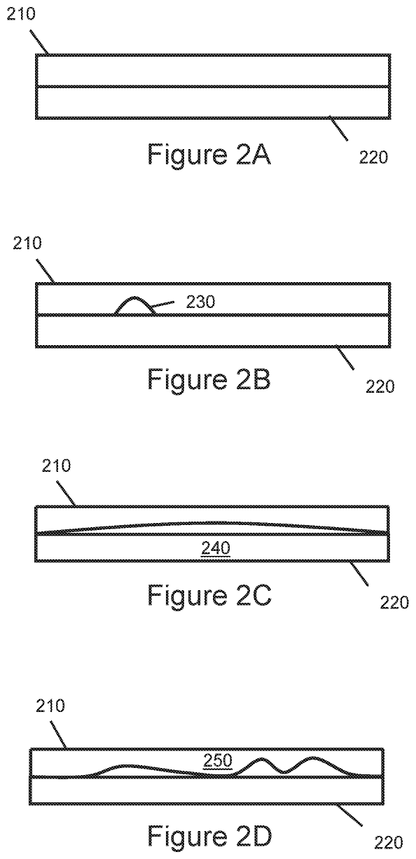

FIG. 2A is a simplified schematic diagram showing an example of a contact 200 between an enclosure 210 and substrate 220. In the example shown in FIG. 2A the contact between the enclosure 210 and substrate 220 is perfect. In particular, there are no defects in the contact such that an aperture forms. This idealised case does not happen in practice and therefore apertures that are formed around the contact zones between any enclosure and the substrate should be taken in to account when constructing a Faraday cage.

FIGS. 2B-2D are simplified schematic diagrams of a substrate and enclosure. FIGS. 2B-2D show different types of apertures that occur at the points of contact of the substrate and enclosure due to different effects. In FIG. 2B, the enclosure 210 comprises a defect 230. A defect may arise during the manufacturing process of the enclosure 210, for example. The enclosure 210 contacts the substrate 210 in the regions outside of the defect. Thus, as long as the maximum size of the defect is less than λ/20 where lambda is the smallest wavelength of an electrical signal of components attached to the substrate, the enclosure will still perform its' function as a Faraday cage.

FIG. 2C is a simplified schematic diagram showing an aperture 240 that has arisen from a bowing effect in the enclosure 210, This is another effect that may arise from an imperfect manufacturing process, for example. In this case, the aperture 240 spans the width over which the enclosure 210 has bowed away from the top surface of the substrate 220.

FIG. 2D is a simplified schematic diagram showing a highly non-linear shaped edge 250 enclosure 210. In practice, the edge of the enclosure 210 which contacts the substrate 220 will often have a large number of irregularities, Each such irregularity may expand into an aperture along the region of contact between the substrate 22 and the enclosure 210.

In addition to the apertures shown in FIGS. 2B-2D the enclosure may comprise one or more further apertures. A first example is a deliberate opening formed in the aperture to connect the circuit assembly to one or more external devices or power outlets. In this case, the size of apertures should also be considered when manufacturing the circuit board assembly.

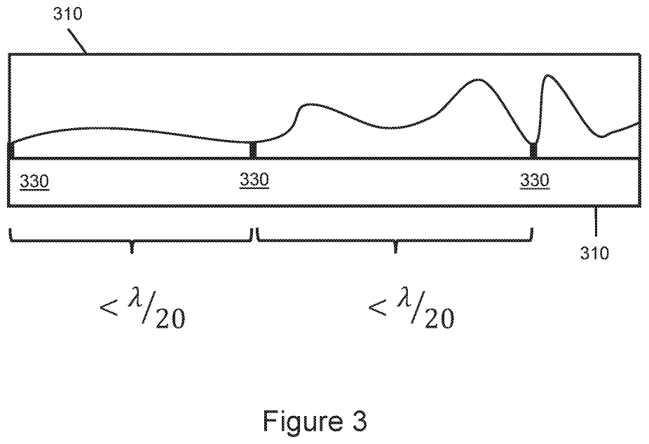

FIG. 3 is a simplified schematic diagram of a section of a circuit board assembly 300, according to an example. In the circuit board assembly 300 shown in FIG. 3 there is shown an enclosure 310 and substrate 320. The enclosure 310 is coupled to the substrate 320 at locations 330 along the region of contact. The locations 330 correspond to the locations 140 shown in FIG. 1. Solder material is deposited at each of the locations 330. The enclosure 310 is soldered to the substrate 320 at the locations 330.

The enclosure 310 exhibits an irregular and non-linear shaped contact edge with the substrate 320. Consequently, apertures are formed in the region where the enclosure meets the substrate. In the example shown in FIG. 3, the locations 330 at which the enclosure 310 is coupled to the substrate 320 are such that maximum aperture size is less than λ/20 where λ is the wavelength determined from equation (1) above. In particular, the largest aperture size in the section of the circuit board assembly shown in FIG. 3 is small enough that the enclosure shields the components attached to the substrate 320 from electromagnetic radiation. If the remaining points of contact are such that the largest aperture size is less than λ/20, overall the enclosure 310 forms a Faraday cage around the substrate 320.

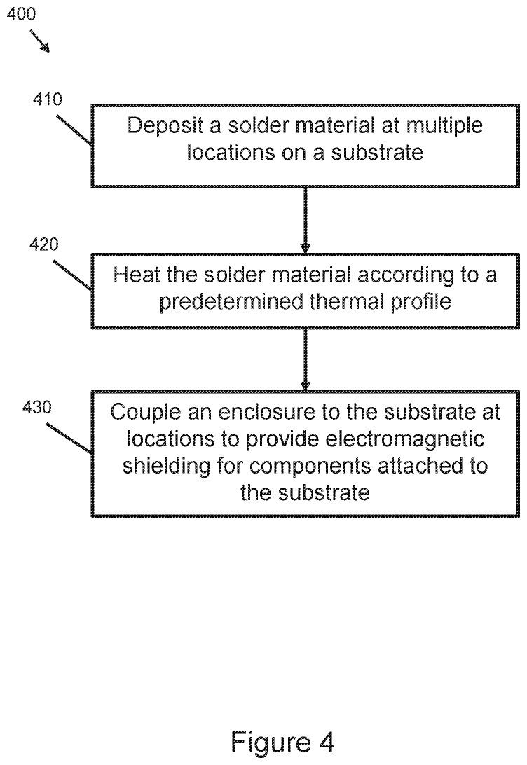

FIG. 4 is a flow diagram showing a method 400 for electromagnetically shielding a circuit board assembly, according to an example. The method 400 shown in FIG. 4 may be implemented in conjunction with the examples described herein. In particular, the method 400 may be implemented during an SMT process, for example, such that no additional manufacturing processes need to be performed in order to include the protrusions 170 shown in FIG. 1.

At block 410, solder material is deposited at multiple locations on a substrate. According to examples, solder material may be deposited from a solder depositing apparatus, that has access to a supply of solder material. The locations are arranged such that a size of a largest aperture of the circuit board assembly is below a pre-determined threshold size value. According to an example, the method 400 may comprise a further step of determining one or more locations on the substrate to deposit solder material. In one case, the pre-determined threshold size value is determined from frequencies associated to components attached to the substrate.

In one example, depositing solder material at a location comprises: laying a stencil over the substrate; and depositing solder material on to the stencil. A stencil may comprise at least one opening that determines the location where the solder material is deposited on to the substrate. The solder material may be deposited on the stencil to form one or more protrusions of a pre-determined height on the substrate. The aforementioned deposition of solder material on the substrate, is in certain examples, performed in conjunction with a SMT process.

At block 420, the solder material is heated according to a predetermined thermal profile. In certain examples described herein the thermal profile specifies a time period and a temperature value, at which the solder material should be heated for to melt the solder material and allow a protrusion to form on the surface of the substrate. This process is, for example, an SMT process as described herein.

At block 430, an enclosure is coupled to the substrate at the locations where the solder material was deposited to provide an electromagnetic shielding for components attached to the substrate. Since the locations of the solder material are chosen such that the any apertures formed in the circuit board assembly are below a pre-determined threshold size, it is possible to ensure that the resulting circuit board assembly and its electrical components are sufficiently protected against electromagnetic radiation.

The methods and apparatus described herein provide a convenient and efficient way of shielding a PCB against electromagnetic radiation. The method described provides a way of attaching a shielding enclosure such that the resulting holes in the overall structure are smaller than a pre-determined threshold, thus guaranteeing when the threshold is sufficiently small, that the enclosure forms a Faraday cage around the PCB. This protects the electrical components from harmful effects caused by electromagnetic radiation. In contrast to other known methods the methods described herein can be used in conjunction with a surface mount technology process. The points of contact between the shielding enclosure and the PCB are formed for protrusions of solder material which can be placed on the PCB at the same time that the electrical components are soldered on to the PCB. This provides a particularly efficient and method of manufacturing that can be used in conjunction with SMT processes.

Examples in the present disclosure can be provided as methods, systems or machine-readable instructions, such as any combination of software, hardware, firmware or the like. Such machine-readable instructions may be included on a computer readable storage medium (including but not limited to disc storage, CD-ROM, optical storage, etc.) having computer readable program codes therein or thereon.

The present disclosure is described with reference to flow charts and/or block diagrams of the method, devices and systems according to examples of the present disclosure. Although the flow diagrams described above show a specific order of execution, the order of execution may differ from that which is depicted. Blocks described in relation to one flow chart may be combined with those of another flow chart. In some examples, some blocks of the flow diagrams may not be needed and/or additional blocks may be added. It shall be understood that each flow and/or block in the flow charts and/or block diagrams, as well as combinations of the flows and/or diagrams in the flow charts and/or block diagrams can be realized by machine readable instructions.

The machine-readable instructions may, for example, be executed by a general-purpose computer, a special purpose computer, an embedded processor or processors of other programmable data processing devices to realize the functions described in the description and diagrams. In particular, a processor or processing apparatus may execute the machine-readable instructions. Thus, modules of apparatus may be implemented by a processor executing machine-readable instructions stored in a memory, or a processor operating in accordance with instructions embedded in logic circuitry. The term ‘processor’ is to be interpreted broadly to include a CPU, processing unit, ASIC, logic unit, or programmable gate set etc. The methods and modules may all be performed by a single processor or divided amongst several processors.

Such machine-readable instructions may also be stored in a computer readable storage that can guide the computer or other programmable data processing devices to operate in a specific mode.

For example, the instructions may be provided on a non-transitory computer readable storage medium encoded with instructions, executable by a processor.

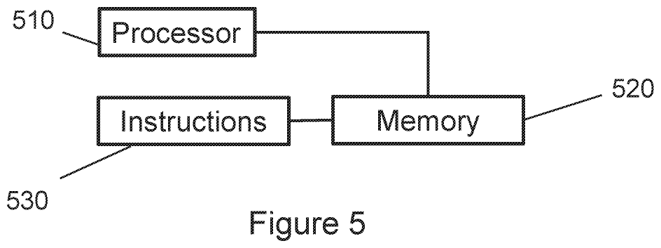

FIG. 5 shows an example of a processor 510 associated with a memory 520. The memory 520 comprises computer readable instructions 530 which are executable by the processor 510. The instructions 530 comprise instruction to determine one or more locations to deposit solder material on a substrate; control the deposition of solder material on the substrate at the one or more locations; access a thermal profile specifying at least a temperature and time period; and control a heat source to heat the solder material according to the thermal profile, wherein the locations are arranged such that a size of a largest aperture between an enclosure coupled to the substrate at the one or more locations, is below a pre-determined threshold size value

Such machine-readable instructions may also be loaded onto a computer or other programmable data processing devices, so that the computer or other programmable data processing devices perform a series of operations to produce computer-implemented processing, thus the instructions executed on the computer or other programmable devices provide an operation for realizing functions specified by flow(s) in the flow charts and/or block(s) in the block diagrams.

Further, the teachings herein may be implemented in the form of a computer software product, the computer software product being stored in a storage medium and comprising a plurality of instructions for making a computer device implement the methods recited in the examples of the present disclosure.

While the method, apparatus and related aspects have been described with reference to certain examples, various modifications, changes, omissions, and substitutions can be made without departing from the spirit of the present disclosure. In particular, a feature or block from one example may be combined with or substituted by a feature/block of another example.

The word “comprising” does not exclude the presence of elements other than those listed in a claim, “a” or “an” does not exclude a plurality, and a single processor or other unit may fulfil the functions of several units recited in the claims.

The features of any dependent claim may be combined with the features of any of the independent claims or other dependent claims.

1. A method for electromagnetically shielding a circuit board assembly, the method comprising:
depositing a solder material at multiple locations on a substrate;
heating the solder material according to a predetermined thermal profile; and
coupling an enclosure to the substrate at the locations to provide an electromagnetic shielding for components attached to the substrate, wherein the locations are arranged such that a size of a largest aperture of the circuit board assembly is below a pre-determined threshold size value.

2. The method of claim 1, comprising determining one or more locations on the substrate to deposit solder material.

3. The method of claim 1, wherein the pre-determined threshold size value is determined from frequencies associated to the components attached to the substrate.

4. The method of claim 1, wherein depositing solder material at a location comprises:
laying a stencil over the substrate; and
depositing solder material on to the stencil;
wherein the stencil comprises at least one opening that determines the location where the solder material is deposited on to the substrate.

5. The method of claim 4, comprising depositing solder material on the stencil to form one or more protrusions of a pre-determined height on the substrate.

6. The method of claim 1, comprising forming the circuit board assembly according to a surface mount technology process.

7. The method of claim 1, comprising externally connecting the circuit board assembly via an aperture provided in the enclosure.

8. The method of claim 1, wherein the pre-determined thermal profile specifies a time period and a temperature value.

9. A circuit board assembly comprising:
A substrate;
one or more components connected to the substrate;
an enclosure connected to the substrate at a plurality of locations, the enclosure shielding the components from electromagnetic interference;
wherein the size of a largest aperture of the circuit board apparatus is below a pre-determined threshold size value.

10. The circuit board assembly of claim 9, wherein the pre-determined threshold size value is determined based on a maximum frequency of the one or more connected components.

11. The circuit board assembly of claim 9, wherein the plurality of locations at which the enclosure is connected to the substrate are pre-determined, such that the size of the largest aperture between the enclosure and the substrate is below the pre-determined threshold size value.

12. The circuit board assembly of claim 9, wherein the enclosure comprises an aperture to connect the one or more components connected to the substrate to an external connection.

13. A non-transitory machine-readable storage medium encoded with instructions executable by a processor, to:
determine one or more locations to deposit solder material on a substrate;
control the deposition of solder material on the substrate at the one or more locations;
access a thermal profile specifying at least a temperature and time period; and
control a heat source to heat the solder material according to the thermal profile,
wherein the locations are arranged such that a size of a largest aperture between an enclosure coupled to the substrate at the one or more locations, is below a pre-determined threshold size value.
